(19) United States
(12) Patent Application Publication
(10) Pub. No.: US 2022/0394372 A1
(43) Pub. Date: Dec. 8, 2022

(54) METHOD FOR INITIALIZING A LONG-TERM-STORAGE MODE FOR A HEARING INSTRUMENT AND HEARING INSTRUMENT

(71) Applicant: Sivantos Pte. Ltd., Singapore (SG)

(72) Inventors: Chuan En Andrew Ong, Singapore (SG); Gee Heng Ler, Georgetown (MY); Chee Kong Siew, Singapore (SG); Heng Goh Yap, Singapore (SG); Shuang Simon Ren, Singapore (SG)

(21) Appl. No.: 17/830,547

(22) Filed: Jun. 2, 2022

(30) Foreign Application Priority Data
Jun. 2, 2021 (DE) 10 2021 205 635.0

(51) Int. Cl. H04R 1/10; H02J 7/00; H04R 25/00

(52) U.S. Cl. CPC H04R 1/1025; H02J 7/0048; H04R 25/602; H04R 2225/31

(57) ABSTRACT

A method for initializing a long-term-storage mode for a hearing instrument having a rechargeable battery cell includes predetermining an upper limiting value of a parameter for a state of charge of the rechargeable battery cell for long-term storage of the hearing instrument. An actual value, actually present, of the parameter for the state of charge is measured within an activation routine for long-term storage. The measured actual value of the parameter for the state of charge is compared with the upper limiting value of the parameter for the state of charge, and if the measured actual value of the parameter lies above the upper limiting value, the battery cell is discharged at least until the parameter has reached the predetermined upper limiting value, and the hearing instrument is placed into a long-term-storage mode. A hearing instrument is also provided.

### CROSS-REFERENCE TO RELATED APPLICATION

This application claims the priority, under 35 U.S.C. § 119, of German Patent Application DE 10 2021 205 635.0, filed Jun. 2, 2021; the prior application is herewith incorporated by reference in its entirety.

### FIELD AND BACKGROUND OF THE INVENTION

The invention relates to a method for initializing a long-term-storage mode for a hearing instrument that has a rechargeable battery cell. The invention further relates to a hearing instrument with a rechargeable battery cell.

A hearing instrument is generally to be understood as a device that has been set up to generate an acoustic signal and to supply it to an auditory system of a user of the hearing instrument. In that connection, the acoustic signal may be generated by a loudspeaker or by a comparable acoustic output transducer that is suitable to generate, from an electrical output signal, corresponding air-pressure oscillations which constitute the acoustic signal in a surrounding atmosphere—accordingly, also by a thermoacoustic transducer, for example. In particular, a hearing instrument may have a rechargeable, preferentially integrated, battery cell for its operation. In that connection, hearing instruments may be embodied by headphones, headsets, so-called earbuds or hearables, but also by hearing aids.

A hearing aid is generally to be understood as a hearing instrument that has been provided and set up to correct or to compensate for an auditory weakness of the user. For that purpose, the hearing aid has at least one electroacoustic input transducer—for example, in the form of a microphone—and a signal-processing device, the input transducer generating from an ambient sound a corresponding electrical input signal which is processed in the signal-processing device in a manner depending on the auditory weakness of the user to be compensated, to form the electrical output signal, and in the process may be amplified and/or compressed, in particular in a frequency-dependent manner. In particular, therefore, earbuds that possess the stated functions may also be regarded as hearing aids.

If a hearing instrument is not used over a relatively long period, diverse preconditions for long-term storage have to be satisfied for durability of the battery cell, depending on the type thereof. In the case of long-term storage without utilization of the hearing instrument, on one hand an excessive state of charge of the battery may have the result that the full charging capacity for the battery cell can no longer be attained when operation is resumed. On the other hand, too low a state of charge prior to safekeeping may result in a deep discharge which may permanently damage the battery cell or even destroy it.

In order, therefore, to be able to survive the length of time from completion of the manufacture of a hearing instrument up until its shipment to an end customer without the stated hazards for the battery cell, appropriate protective measures are usually adopted at the factory. However, in the case where the user wishes to store a hearing instrument again over a relatively long period after initial operation and use, such protective measures are not ordinarily available to him/her, as a consequence of the implementation at the factory.

### SUMMARY OF THE INVENTION

It is accordingly an object of the invention to provide a method for initializing a long-term-storage mode for a hearing instrument and a hearing instrument, which overcome the hereinafore-mentioned disadvantages of the heretofore-known methods and instruments of this general type, in which the method makes long-term storage possible, even after use or initial operation, that conserves the battery cell of the hearing instrument as much as possible and in which an appropriate hearing instrument that has been set up for a long-term storage conserves the battery as much as possible.

With the foregoing and other objects in view there is provided, in accordance with the invention, a method for initializing a long-term-storage mode for a hearing instrument that has a preferentially integrated rechargeable battery cell, wherein for a long-term storage of the hearing instrument an upper limiting value of a parameter for a state of charge of the rechargeable battery cell is predetermined, within the scope of an activation routine for a long-term storage, an actual value, actually present, of the parameter for the state of charge of the battery cell is measured, the measured actual value of the parameter for the state of charge of the battery cell is compared with the upper limiting value of the parameter for the state of charge, and in the case where the measured actual value of the parameter lies above the upper limiting value for the parameter the battery cell is discharged at least until the parameter for the state of charge has reached the predetermined upper limiting value, and the hearing instrument is placed into a long-term-storage mode. Advantageous and—in part, viewed individually—inventive configurations are the subject matter of the dependent claims and of the following description.

With the objects of the invention in view, there is also provided a hearing instrument encompassing a rechargeable battery cell, a measuring device for measuring an actual value of a parameter for a state of charge of the battery cell, a comparing device for comparing the measured actual value of the parameter with an upper limiting value of the parameter for the state of charge of the battery cell, predetermined for a long-term storage of the hearing instrument, and a discharging device which, within the scope of an activation routine for a long-term storage of the hearing instrument in the case where the measured actual value of the parameter of the state of charge of the battery cell lies above the upper limiting value, has been set up to discharge the battery cell of the hearing instrument at least until the parameter for the state of charge has reached the upper limiting value, the hearing instrument having been set up to assume a long-term-storage mode within the scope of the activation routine for long-term storage when the state of charge that corresponds to the predetermined upper limiting value of the parameter is attained.

The hearing instrument according to the invention shares the merits of the method according to the invention. The advantages specified for the method and for its further developments can be carried across, with due alteration of details, to the hearing instrument.

The discharging device of the hearing instrument according to the invention may, in particular, be embodied by a processor unit in which all of the functions of the signal-processing of the hearing instrument have been implemented, so that the discharge can be effected by the operation (where appropriate, without generation of an output signal) of the processor unit.

The term “rechargeable battery cell” encompasses, in particular, any energy-storage device that, on one hand, has been provided and set up to supply the hearing instrument with energy in ongoing operation and/or in a stand-by mode, and, on the other hand, can be repeatedly recharged for the energy supply, for instance by using an appropriate charging unit which may have been adapted, in particular, for use in conjunction with the hearing instrument, perhaps by using appropriate terminals for transfer of energy or a device for wireless transfer of energy. The rechargeable battery cell has preferably been integrated into the hearing instrument in such a manner that the user does not have to take the battery cell out of the hearing instrument for a charging process. In particular, removal of the battery cell from the hearing instrument has not been provided for and may not be possible at all without potentially endangering components of the hearing instrument. The battery cell may be based on lithium ion, in particular for the charging and discharging mechanism.

The term “long-term storage” of the hearing instrument in this connection, in particular encompasses a storage or safekeeping of the hearing instrument that far exceeds a conventional period for taking the hearing instrument off overnight or until the next usage in the case of a regular sporting activity—that is to say, that extends, in particular, over one month to several months. However, a long-term storage may also already occur in the case of a pause in operation amounting to a few weeks (for instance, during a vacation of the user). The long-term-storage mode in this connection is to be interpreted, in particular, as a concrete configuration that has been optimized for the long-term storage with regard to the durability of the battery cell, and that relates to all of the operating parameters of a power management of the hearing instrument.

In particular, a voltage applied to the battery cell and/or a current emitted by the battery cell may have been provided as a parameter for a state of charge of the rechargeable battery cell. In particular, there is a monotonic relationship between the parameter and the state of charge.

In this sense, the predetermined upper limiting value for the parameter for a long-term storage of the hearing instrument has been provided, in particular, in such a manner that the state of charge corresponding to the upper limiting value ensures the highest possible charging capacity for the battery cell, even after months without charging and without an external drain of power from the battery cell, on one hand, and on the other hand protects the battery cell effectively against a deep discharge during this period without draining power and charging. The state of charge corresponding to the upper limiting value, and/or the associated upper limiting value of the parameter, may in this connection have been predetermined, in particular by a manufacturer of the battery cell, and/or can be ascertained on the basis of measurements, in the course of which the battery cell is recharged in each instance to a certain proportion of the maximum charging capacity, and after a standardized period of safekeeping the extent to which the maximum charging capacity has been reduced by the storage is ascertained. The state of charge corresponding to the upper limiting value then preferably results as that proportion of the maximum charging capacity in the initial state (that is to say, prior to storage) for which the largest possible proportion of the maximum charging capacity (prior to storage) can still be achieved after storage. The state of charge may be specified in Wh or in % of the maximum charging capacity for the battery cell. Correspondingly, the upper limiting value can be ascertained therefrom.

The term “activation routine for long-term storage,” in particular is to be understood as the process by which the instrument is placed into the long-term-storage mode. The activation routine for long-term storage preferentially runs automatically after an initialization. The long-term-storage mode is consequently initialized on the basis of the activation routine for long-term storage, in which connection the routine can likewise be started automatically or can also be started up by a user input. For the activation routine for long-term storage, a value currently actually obtaining of the parameter for the state of charge—that is to say, the actual value of the parameter—is measured and is compared with the predetermined upper limiting value which is accordingly regarded as a maximum for a state of charge for a long-term storage of the hearing instrument. The comparison can be carried out, for instance, by a circuit for power management (power-management integrated circuit (PMIC)) or by a computational process in a processor unit of the hearing instrument, which has been provided and set up therein for generation of an acoustic output signal.

Now if the measured actual value of the parameter lies above the upper limiting value provided and predetermined correspondingly for the long-term-storage mode, and if, accordingly, the state of charge actually obtaining is correspondingly above the state of charge regarded as maximal for long-term storage, the battery cell is discharged at least until the actual value of the parameter reaches the upper limiting value as a consequence of the reduced state of charge (and consequently the battery cell no longer exceeds the state of charge regarded as maximal for long-term storage). Such a discharge may be effected, for instance, by the instrument being placed into a standby mode or an extended standby mode or a normal mode (utilizing all the conventional functions of at least the processing unit), so that the state of charge of the battery cell is gradually reduced by the continuous drain of power during the mode. Where appropriate, the, or each, electroacoustic output transducer of the hearing instrument can be deactivated for the process of discharging, so that no unwanted noises are generated at the place of storage (for instance, a drawer or the like), and the discharging is achieved primarily through the power for the processor unit. This permits the user, after starting the activation routine for long-term storage, to already place or accommodate the hearing instrument at the designated place for long-term storage.

If a comparison of the measured actual value of the parameter for the state of charge of the battery cell with the predetermined upper limiting value for the parameter is effected merely in discrete steps (whether for reasons of digitization of the measured parameter—that is to say, for example, of a voltage—or as a consequence of a digitization and consequently discretization of the corresponding actual value), a discharge of the battery cell should preferably occur until the actual value of the parameter no longer lies above the predetermined upper limiting value, and consequently in the course of the discretization also falls, where appropriate, incrementally below the upper limiting value (and consequently it is ensured that the state of charge actually obtaining no longer exceeds the state of charge regarded as maximal for long-term storage). As soon as this is the case, the hearing instrument is placed into the long-term-storage mode.

The long-term-storage mode in this connection has to be configured, in particular, in such a way that a further drain of energy from the battery cell during the long-term storage, and also other leakage currents or similar, are prohibited as far as possible, in order, on one hand, to keep the available state of charge as high as possible for renewed use after long-term storage, and, on the other hand, to minimize the risk of a deep discharge as far as possible. This can be done, in particular, by the battery cell being isolated from the PMIC for this purpose and, where appropriate, remaining connected only to a protective circuit for protection against deep discharge and/or short circuits.

The stated method permits the hearing instrument to be placed into a state—even after shipment to the user and, in particular, after an initial operation by the user—in which a long-term storage over several weeks or even months is possible for the hearing instrument without imminent damage to, or lasting deterioration of, the battery cell of the hearing instrument.

In the case where the measured actual value of the parameter for the state of charge of the battery cell lies below the upper limiting value for the parameter, the hearing instrument is preferably placed into the long-term-storage mode. This means, in particular, that no discharging is required within the scope of the activation routine for long-term storage if it is ascertained at the start of the activation routine that the actual value of the parameter for the state of charge already lies below the predetermined upper limiting value (and accordingly the present state of charge is not impermissibly high for long-term storage). Instead of this, the hearing instrument can be immediately placed into the long-term-storage mode without a process for discharging the battery cell.

A lower limiting value of the parameter for the state of charge of the rechargeable battery cell is preferably predetermined for long-term storage of the hearing instrument, in which connection in the case where the measured actual value of the parameter for the state of charge of the battery cell lies below the lower limiting value for the parameter a prompt for a recharging of the battery cell is output to a user of the hearing instrument. The prompt can be output, in particular, in acoustic form as an appropriate signal tone or as a message through the output transducer of the hearing instrument, but, in particular, can also be displayed through an auxiliary device that is capable of being connected to the hearing instrument.

In the case where the measured actual value of the parameter for the state of charge of the battery cell lies between the upper limiting value and the lower limiting value for the parameter, the hearing instrument is favorably placed into the long-term-storage mode. This means, in particular, that no preceding discharge process takes place for the long-term-storage mode.

The activation routine for long-term storage is preferentially initiated by the user of the hearing instrument by using a user input. This allows the user to protect the battery cell efficiently if he/she is intending not to use the hearing instrument in the long term, and accordingly to keep it safe. In particular, the user input is entered by the user of the hearing instrument through an appropriate application by using an auxiliary device—such as, for example, a smartphone or smartwatch—that is capable of being connected to the hearing instrument for data-processing.

The prompt for a recharging of the battery cell is preferably output to the user of the hearing instrument by using the auxiliary device—that is to say, for example, as an appropriate display on a screen.

A utilization of the hearing instrument is favorably checked repeatedly and preferably with a first periodicity, in which connection the activation routine for long-term storage is initiated automatically as soon as no utilization of the hearing aid has occurred for at least a first time-period. The utilization of the hearing aid is preferably checked automatically and, in particular, by the hearing instrument itself (for example, in the form of a function in the processor unit). This enables an initialization of the long-term-storage mode even when the user has not himself/herself started up the activation routine for long-term storage, for example as a consequence of forgetting. The first time-period may preferably amount to a period from three days to two months, particularly preferably up to one month.

Outside the activation routine for long-term storage, the measured actual value of the parameter for the state of charge of the battery cell is expediently compared repeatedly with the predetermined lower limiting value for the parameter, preferably with a second periodicity, in which connection in the case where the measured actual value lies below the lower limiting value a prompt for a recharging of the battery cell is output to the user of the hearing instrument. This is intended, in particular, to ensure that the battery cell has, in principle, been sufficiently recharged to be able to switch over to the long-term-storage mode even when the initialization thereof occurs automatically after an appropriately detected relatively long non-utilization of the hearing instrument. The first time-period may preferably amount to a period from three days to two months, particularly preferably up to two weeks.

In this way, a utilization of the hearing instrument and, at the same time, the state of charge of the battery cell can, for example, be checked. If the actual value lies above the lower limiting value (and, correspondingly, the actual state of charge lies above a state of charge regarded as minimal for long-term storage), and no utilization of the hearing instrument obtains, a wait can be observed, at least until a further check, without outputting an instruction to the user to charge the battery cell, since in the case where no utilization obtains also at the time of the next check the activation routine for long-term storage might still be initiated automatically as a consequence of the presumably still adequate state of charge.

For the placement into the long-term-storage mode, the hearing instrument is preferably switched off. This means, in particular, that no functions whatever are carried out in the processor unit of the hearing instrument, and, where appropriate, an operating system has no longer been loaded in a working memory of the processor unit, so that the processor unit no longer displays any power consumption whatever (possibly except for unwanted leakage currents). As a result, the state of charge of the battery cell remains particularly stable in the long-term-storage mode. In particular, a communication device of the hearing instrument has also been de-energized.

For the placement into the long-term-storage mode, the battery cell is expediently isolated by circuitry from the PMIC of the hearing instrument. In this way, undesirable leakage currents, in particular into the processor unit, can also be prohibited as far as possible. Such leakage currents may amount to up to 4 μA in the case of a battery cell that has been configured for a mean output of 20 mA, for example.

In the long-term-storage mode, the battery cell has preferably been connected to a battery-protection circuit, in particular for protection against a deep discharge and/or against short circuits. If the battery cell has also been connected to such a protective circuit during normal operation, the connection is also preserved in the long-term-storage mode. If such a connection to the protective circuit does not obtain during normal operation, it is established as part of the initialization of the long-term-storage mode. Possible leakage currents that result from this are almost negligible as a consequence of the architecture of the protective circuit, and can be limited to 40 nA, for example for a battery cell that has been configured for a mean output of 20 mA.

A voltage applied to the battery cell is favorably measured or predetermined as parameter for the state of charge of the battery cell. This means, in particular, that a corresponding voltage value is predetermined as an upper and, where appropriate, a lower limiting value, and a value of the voltage applied to the battery cell is measured as an actual value. A voltage measurement is particularly easy to realize technically and does not ordinarily require any additional components expressly provided for this purpose in the hearing instrument. The voltage applied to the battery cell is preferably ascertained with the aid of an analog-to-digital converter.

In an advantageous configuration, a communication device and/or an output transducer of the hearing instrument are/is deactivated within the scope of the activation routine for long-term storage for a discharging of the battery cell at least until the parameter for the state of charge reaches the upper limiting value. By way of a “communication device” in this connection, in particular an antenna for a Bluetooth connection and/or WLAN connection has been provided. Switching the communication device off permits the hearing instrument to be kept in a charging device for the hearing instrument for the long-term switching-off routine and, where appropriate, also for the long-term-storage mode without interference for the charging device being able to occur. Where appropriate, for this purpose, a charging mode for the charging device is deactivated, in order to prohibit an unwanted charging.

Other features which are considered as characteristic for the invention are set forth in the appended claims.

Although the invention is illustrated and described herein as embodied in a method for initializing a long-term-storage mode for a hearing instrument and a hearing instrument, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, cross-sectional view and block diagram of a hearing instrument configured as a hearing aid;

FIG. 2 is a block diagram illustrating a method for placing the hearing aid according to FIG. 1 into a long-term-storage mode; and

FIG. 3 is a block diagram illustrating an alternative method for initializing the long-term-storage mode according to FIG. 2.

### DETAILED DESCRIPTION OF THE INVENTION

Referring now in detail to the figures of the drawings, in which parts and quantities corresponding to one another have been provided with the same reference symbols, and first, particularly, to FIG. 1 thereof, there is seen a hearing instrument 1, which in the present case is embodied by a hearing aid 2, and is represented schematically in a block diagram. The hearing aid 2 has a microphone 4 which has been set up to generate a corresponding electrical input signal (not represented) from an acoustic signal pertaining to an environment of the hearing aid 2. The microphone 4 is connected to a processor unit 6 which, in particular, has a signal processor, with at least one processor core, and a working memory that is capable of being addressed by the processor core (none of these being represented in any detail). In particular, a non-volatile memory has also been implemented in the processor unit 6, in which basic functions, operating programs and operating modes of the hearing aid 2 have been stored for operation. The input signal generated by the microphone 4 is processed in the processor unit 6 in accordance with the audiological requirements of the user of the hearing aid 2 for the purpose of compensating for the auditory weakness, and, in particular, is amplified or compressed in a frequency-dependent manner. In this process, an output signal is generated in the processor unit 6, which is output to an electroacoustic output transducer 8 of the hearing aid 2, which for this purpose has been connected appropriately to the processor unit 6. The electroacoustic output transducer 8 is embodied in the present case by a loudspeaker, and converts the output signal generated by the processor unit 6 into a corresponding acoustic output signal (not represented) which is supplied to the auditory system of the user of the hearing aid 2.

For operation, the hearing aid 2 has a rechargeable battery cell 10 which in the present case is embodied by a lithium-ion cell. The battery cell 10 is connected through a protective circuit 13 to a PMIC 12 which has been set up for functions of battery management, voltage regulation, power-flow and charging of the battery cell 10. The connection of the battery cell 10 to the PMIC 12 in this case has been configured, in particular, in such a manner that the battery voltage that is applied to the two poles of the battery cell 10 is capable of being tapped and, in particular, measured. The connection of the PMIC 12 to the protective circuit 13 (represented by a dashed line) may, in addition, be interrupted by the PMIC 12 (for example, through an appropriate switching logic).

The PMIC 12 is connected to the processor unit 6, in order to supply the processor unit with energy for the signal-processing. A supply of energy to the output transducer 8 can be effected, in particular, through the processor unit 6, but the output transducer 8 may also draw its power for generating the acoustic output signal directly from the PMIC 12 separately (not represented). The hearing aid 2 has, in addition, a communication device 14 which in the present case is provided as a Bluetooth-capable antenna 15 which is connected to the processor unit 6 and which has been set up to establish a connection to an external auxiliary device (not represented) such as a smartphone, or even to a further hearing aid (not represented) in the case of a binaural hearing aid system. For this purpose, the antenna 15 has been connected to the processor unit 6, in order to receive a corresponding transmitted signal (not represented) from the processor unit. The power supply for the antenna 15 is likewise effected through the processor unit 6.

In the case where the user of the hearing aid 2 would like to store it for a relatively long period after initial operation, so that, in particular, no operation of the hearing aid 2 whatever occurs, the hearing aid 2 is placed into an appropriate long-term-storage mode in a manner yet to be described. This long-term-storage mode is characterized, in particular, in that a state of charge of the battery cell 10 is set to a value that has been optimized for a long-term storage of the hearing aid 2 (and consequently for a long period without charging and without appreciable discharging of the battery cell 10 beyond leakage currents), to the effect that after a termination of the storage—for example, after a few weeks or even months—the battery cell 10 retains as high a charging capacity as possible.

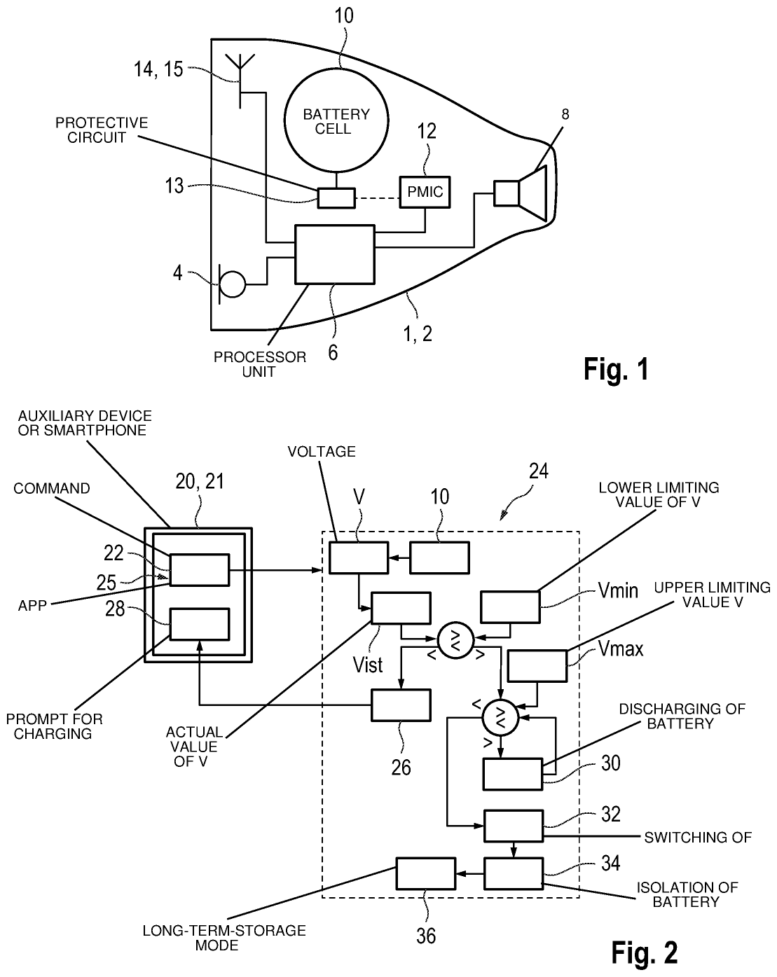

In FIG. 2 a method is represented schematically in a block diagram, through the use of which the hearing aid 2 according to FIG. 1 can be placed into a long-term-storage mode. A user (not represented) transmits a command 22 for initiating an activation routine 24 for long-term storage to the hearing aid 2 through an auxiliary device 20 which in the present case has been configured as a smartphone 21 (a configuration as a smartwatch, tablet or similar is likewise conceivable) and which is capable of being used with the hearing aid 2 according to FIG. 1 through the antenna 15 thereof. This can be effected, for instance, by an app 25 that has been set up for controlling certain functions of the hearing aid 2, and, in particular, for entering the command 22, having been implemented on the smartphone 21, so that the command is passed on appropriately to the hearing aid 2. The activation routine 24 for long-term storage is started up accordingly in the hearing aid 2.

For this purpose, a voltage V applied to the battery cell 10 is drawn upon as a parameter for the state of charge of the battery cell 10. First of all, an actual value Vist, actually present, of the voltage V applied to the battery cell 10 is ascertained. This actual value Vist is compared with a predetermined lower limiting value Vmin for the voltage V as a parameter of the state of charge of the battery cell, with the lower limiting value Vmin being predetermined in such a manner that, as a consequence of the state of charge of the battery cell 10 corresponding to the lower limiting value Vmin in the case of relatively long-term storage, a deep discharge that might totally damage the battery cell 10 is effectively prohibited.

If it is now established that the actual value Vist of the voltage V measured on the basis of the voltage V lies below the predetermined lower limiting value Vmin, and correspondingly the state of charge of the battery cell 10 lies below the state of charge regarded as minimal for long-term storage of the hearing aid 2 (which corresponds to the lower limiting value Vmin for the voltage V), an appropriate charging message 26 is transmitted from the hearing aid 2 to the smartphone 21, and thereupon a prompt 28 for a recharging of the battery cell 10 is output to the user by the smartphone 21 through the screen. The output can, in particular, be effected within the scope of the app 25 which has been installed and implemented on the smartphone 21 for the purpose of controlling the hearing aid 2.

If, however, the measured actual value Vist of the parameter for the state of charge—that is to say, of the voltage V—is greater than the predetermined lower limiting value Vmin, a further comparison of the measured actual value Vist with a predetermined upper limiting value Vmax for the voltage V takes place. This upper limiting value Vmax for the voltage is predetermined in such a manner that, as a consequence of the state of charge of the battery cell 10 corresponding to the upper limiting value Vmax in the case of a relatively long-term storage, a deterioration of the enduring charging capacity is minimized as far as possible.

Now if the measured actual value Vist of the voltage V lies below the predetermined upper limiting value Vmax (and consequently the actual state of charge of the battery cell 10 lies below the state of charge considered to be maximally permissible for long-term storage), a switching off 32 of the hearing aid 2 is undertaken. This switching off 32 involves, in particular, an isolating of the processor unit 6, and, if required separately, also of the further loads from the PMIC 12. Subsequently an isolation 34 of the battery cell 10 from the PMIC 12 takes place. This isolation 34 takes place in such a manner through the protective circuit 13 that the battery cell 10 is thereupon only connected to the protective circuit 13 according to FIG. 1. The protective circuit 13 has been set up to protect the battery cell 10 additionally against short circuits or even against deep discharges during the long-term storage of the hearing aid 2, and displays negligible leakage currents, particularly in comparison with the PMIC 12. After the isolation 34 of the battery cell 10 from the PMIC 12 and the switching off 32 of the hearing aid 2, a long-term-storage mode 36 for the hearing aid 2 has been attained in the present case.

If, on the other hand, the measured actual value Vist of the voltage V lies above the predetermined upper limiting value Vmax, a discharging 30 of the battery cell 10 occurs. The discharging 30 occurs subject to a continuous or repeated checking of the respective actual value Vist of the voltage V at the respective time in comparison with the predetermined upper limiting value Vmax. If the upper limiting value Vmax is reached by the actual value Vist (or if the actual value Vist no longer lies above the upper limiting value Vmax), the switching off 32 of the hearing device 2 described above is undertaken.

By virtue of the measures undertaken in the hearing aid 2 as described, it can be ensured that in the case of a long-term storage of the hearing aid 2, in particular over several months, the battery cell 10 is stored in a (maximum) state of charge optimized for this purpose with regard to the retention of the charging capacity (the upper limiting value Vmax of the voltage V corresponds to this maximum state of charge). In addition, a creeping discharge due to leakage currents is prohibited as far as possible, so that the actual state of charge during storage can be kept permanently above a state of charge predetermined as minimal with regard to a deep discharge (to which the lower limiting value Vmin of the voltage V corresponds).

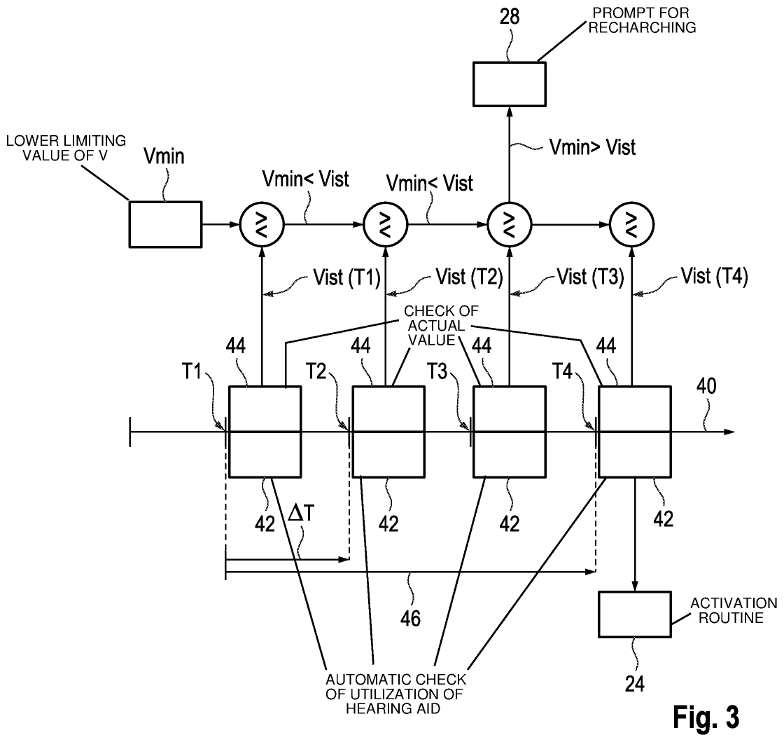

In FIG. 3, an alternative configuration of the method according to FIG. 2 is represented schematically along a timeline 40, in which the activation routine 24 for long-term storage is initiated automatically. At times T1, T2, T3, T4 with a periodicity ΔT, in this configuration an automatic check 42 of a utilization of the hearing aid 2 is effected for this purpose by the hearing aid 2 itself. At the same time, a check 44 of the actual value Vist of the voltage V applied to the battery cell 10 is likewise effected, as described with reference to FIG. 2.

The actual value Vist of the voltage V ascertained at the individual times T1, T2, T3, T4 is compared in each instance with the lower limiting value Vmin predetermined for a long-term storage. If the actual value Vist always lies above the lower limiting value Vmin (that is to say, Vmin<Vist) in the course of the checks 44, no further action takes place. If, however, at one of the times—for instance, at time T3—the measured actual value Vist of the voltage V applied to the battery cell 10—which, after all, constitutes the parameter for the state of charge of the battery cell 10—lies below the lower limiting value Vmin for the voltage V predetermined for long-term storage (that is to say, Vmin>Vist), then a prompt 28 for charging the hearing aid 2 is output, as represented on the basis of FIG. 2.

If, in addition, no utilization of the hearing aid 2 whatever is established in the course of the check 42, at least for a first time-period 46, which in the present example is intended to correspond in an exemplary manner to the time-interval from T1 to T4=3·ΔT (but may also encompass a different period to be suitably chosen by a person skilled in the art), the activation routine 24 for long-term storage according to FIG. 2 is initiated automatically. In this connection, the repeated checking 44 of the actual value Vist of the voltage V is particularly advantageous, since it has to be assumed that in the course of a regular utilization of the hearing aid 2 the user will receive the prompt 28 for charging in the case where the actual value Vist lies below the lower limiting value Vmin, and will also put it into effect accordingly. Even in the case of non-utilization over the first time-period 46, which according to the present embodiment results in the automatic initiation of the activation routine 24 for long-term storage, it may therefore be assumed that the actual value Vist at least does not fall short of the predetermined lower limiting value Vmin (and consequently the actual state of charge of the battery cell 10 does not fall short of the state of charge regarded as minimal for long-term storage, which corresponds to the lower limiting value Vmin), so that in the activation routine 24 for long-term storage according to FIG. 2 the long-term-storage mode 36 can also actually be attained.

The checking 44 of the actual value Vist of the voltage V may also take place at different times than the checking 42 of the utilization of the hearing aid 2. This can be set accordingly, in particular as a function of the usage habits of the user of the hearing aid 2. However, a simultaneous check has the advantage that only one periodic process has to be implemented for both checks 42, 44.

In the preceding embodiments, the hearing instrument 1 has been configured as a hearing aid 2 which has been provided and set up for providing care for an auditory weakness of its user. However, another configuration is readily possible. Accordingly, the hearing instrument 1 according to FIG. 1 may be embodied by an earplug-shaped headphone, wherein voice commands of the user for actuating functions of the headphone are picked up through the microphone 4 and are recognized and processed appropriately in the processor device 6 (from the associated input signal). Similarly, configurations of a hearing instrument 1 without a microphone are also conceivable.

Although the invention has been illustrated and described in detail by the preferred embodiment, the invention is not restricted by the disclosed examples, and other variations may be derived therefrom by a person skilled in the art without departing from the scope of protection of the invention.

The following is a summary list of reference numerals and the corresponding structure used in the above description of the invention.

### LIST OF REFERENCE SYMBOLS

1 hearing instrument
2 hearing aid
4 microphone
6 processor unit
8 output transducer
10 battery cell
12 PMIC
13 protective circuit
14 communication device
15 antenna
20 auxiliary device
21 smartphone
22 command
24 activation routine for long-term storage
25 app, application
26 charging message
28 prompt for charging
30 discharging
32 switching off
34 isolation
36 long-term-storage mode
40 timeline
42 checking (of utilization)
44 checking (of the actual value)
Vist actual value of the voltage
Vmax upper limiting value of the voltage
Vmin lower limiting value of the voltage
T1-T4 times
V voltage

1. A method for initializing a long-term-storage mode for a hearing instrument having a rechargeable battery cell, the method comprising:
predetermining an upper limiting value of a parameter for a state of charge of the rechargeable battery cell for a long-term storage of the hearing instrument; and
carrying out an activation routine for long-term storage by:
measuring an actual value, actually present, of the parameter for the state of charge of the battery cell,
comparing the measured actual value of the parameter for the state of charge of the battery cell with the upper limiting value of the parameter for the state of charge, and
when the measured actual value of the parameter lies above the upper limiting value for the parameter, discharging the battery cell at least until the parameter for the state of charge has reached the predetermined upper limiting value, and entering the hearing instrument into the long-term-storage mode.

2. The method according to claim 1, which further comprises placing the hearing instrument into the long-term-storage mode when the measured actual value of the parameter for the state of charge of the battery cell lies below the upper limiting value for the parameter.

3. The method according to claim 2, which further comprises:
predetermining a lower limiting value of the parameter for the state of charge of the rechargeable battery cell for long-term storage of the hearing instrument; and
outputting a prompt to a user of the hearing instrument for recharging the battery cell when the measured actual value of the parameter for the state of charge of the battery cell lies below the lower limiting value for the parameter.

4. The method according to claim 3, which further comprises placing the hearing instrument into the long-term-storage mode when the measured actual value of the parameter for the state of charge of the battery cell lies between the upper limiting value and the lower limiting value for the parameter.

5. The method according to claim 1, which further comprises initiating the activation routine for long-term storage by a user of the hearing instrument using a user input.

6. The method according to claim 5, which further comprises entering the user input by the user of the hearing instrument through an appropriate application by using an auxiliary device capable of being connected to the hearing instrument for data-processing.

7. The method according to claim 6, which further comprises using the auxiliary device to output a prompt to the user of the hearing instrument for recharging the battery cell.

8. The method according to claim 1, which further comprises:
repeatedly checking a utilization of the hearing instrument; and
automatically initiating the activation routine for long-term storage as soon as no utilization of the hearing instrument has occurred for at least a first time-period.

9. The method according to claim 3, which further comprises:
repeatedly comparing the measured actual value of the parameter for the state of charge of the battery cell with the predetermined lower limiting value for the parameter, outside of the activation routine for long-term storage; and
outputting the prompt for recharging the battery cell to the user of the hearing instrument when the measured actual value lies below the lower limiting value.

10. The method according to claim 1, which further comprises switching off the hearing instrument, for placing the hearing instrument into the long-term-storage mode.

11. The method according to claim 10, which further comprises isolating the battery cell by using circuitry from a circuit for power management of the hearing instrument, for placing the hearing instrument into the long-term-storage mode.

12. The method according to claim 10, which further comprises connecting the battery cell to a battery-protection circuit in the long-term-storage mode.

13. The method according to claim 1, which further comprises measuring or predetermining a voltage applied to the battery cell as the parameter for the state of charge of the battery cell.

14. The method according to claim 13, which further comprises using an analog-to-digital converter to ascertain the voltage applied to the battery cell.

15. The method according to claim 1, which further comprises deactivating at least one of a communication device or an output transducer of the hearing instrument within the activation routine for long-term storage, to discharge the battery cell at least until the parameter for the state of charge reaches the upper limiting value.

16. A hearing instrument, comprising:
a rechargeable battery cell;
a measuring device for measuring an actual value of a parameter for a state of charge of said battery cell;
a comparing device for comparing the measured actual value of the parameter with an upper limiting value of the parameter for the state of charge of the battery cell, the upper limiting value being predetermined for a long-term storage of the hearing instrument;
a discharging device configured to discharge said battery cell at least until the parameter for the state of charge has reached the upper limiting value, within an activation routine for a long-term storage of the hearing instrument when the measured actual value for the parameter of the state of charge of the battery cell lies above the upper limiting value; and
the hearing instrument configured to assume a long-term-storage mode within the activation routine for long-term storage upon attaining a state of charge corresponding to the predetermined upper limiting value of the parameter.
